(19) United States
(12) Patent Application Publication
(10) Pub. No.: US 2007/0121308 A1
(43) Pub. Date: May 31, 2007

(54) Electronic device capable of releasing ESD

(75) Inventor: Chin-Chun Chiang, Taipei City (TW)

Correspondence Address: BIRCH, STEWART, KOLASCH & BIRCH, LLP, 8110 GATEHOUSE ROAD, SUITE 100 EAST, FALLS CHURCH, VA, 22315, US

(73) Assignee: ASUSTeK COMPUTER INC.

(21) Appl. No.: 11/583,000

(22) Filed: Oct. 19, 2006

(30) Foreign Application Priority Data
Nov. 25, 2005 (TW) 094141445

(51) Int. Cl. H05K 9/00

(52) U.S. Cl. 361/818

(57) ABSTRACT

An electronic device capable of releasing ESD includes a housing with a seam, a component installed inside the housing, and a shielding unit installed between the seam and the component. The shielding unit is utilized to guide the charges into the housing through the seam to discharge elsewhere such that the component will not be destroyed by the ESD.

### BACKGROUND OF THE INVENTION

1. Field of the Invention

The present invention generally relates to an electronic device, and more specifically, to an electronic device that is capable of releasing ESD.

2. Description of the Prior Art

There is electrostatic everywhere. Though the electrostatic discharge (ESD) is almost insensible and not commonly taken seriously, it does cause damage to circuits and electronic products, especially the circuits operated at high frequencies may be damaged by only tens of volts. Therefore, it becomes an important issue. to control the ESD in circuit design and manufacturing electronic products.

In the safety certifications, there are requirements about ESD resistance as well. It is easy for the electrostatic charges to enter the inside of a product along a seam on the housing and to discharge electricity. The elements located in the path of discharge are destroyed thereof. Please refer to FIG. 1. FIG. 1 is a diagram of a conventional notebook 10. The housing of the notebook 10 is not hermetically sealed and having many seams as other common electronic devices. For example, as illustrated in FIG. 1, there are a seam 101 and a seam 102 on the housing of the main machine, and there is a seam 103 between the display panel and the surrounding housing. When an ESD test is held, or ESD just happens spontaneously around the notebook 10, charges are shot into the notebook 10 through the seams on the housing and destroy the circuits and components of the notebook 10. For instance, charges that enter the notebook 10 through the seam 103 will possibly destroy a controller of the display panel of the notebook 10.

In the prior art, one of the most common methods to resist the destruction by ESD is to install capacitors on the circuit board. Please refer to FIG. 2. FIG. 2 illustrates a cross-section view of an electronic device 200 of the prior art. There is a seam 201 on the housing 20 of the electronic device 200, right above an IC 203 installed on a circuit board 205 of the electronic device 200. When an ESD test is held, or ESD happens spontaneously around the electronic device 200, it is easy for charges to enter the electronic device 200 through the seam 201 and hence to destroy the IC 203. As shown in FIG. 2, the conventional electronic device 200 adopts a capacitor 206 installed on the circuit board 205 in order to release the ESD.

### SUMMARY OF THE INVENTION

It is therefore an objective of the claimed invention to provide an electronic device equipped with a shielding unit to change the path of discharge in order to keep important components away from being destroyed by the electrostatic discharge.

The claimed invention discloses an electronic device capable of releasing ESD. The present electronic device includes a shielding unit and related discharging circuit. The shielding unit is installed within a housing having a seam, between the seam of the housing and a component to be protected. The shielding unit is utilized to conduct the charges that are shot into the housing through the seam.

The spirit of the present invention is to install a shielding unit between a seam of the housing and a component to be protected in order to conduct charges to discharge elsewhere, that is, to change the discharge path, hence to protect the important components from ESD.

The present electronic device capable of releasing ESD further includes a filter having a first end coupled with the shielding unit and a second end coupled to ground.

The present electronic device capable of releasing ESD further includes a transient voltage suppressor having a first end coupled with the shielding unit and a second end coupled to ground.

The present electronic device capable of releasing ESD further includes a varistor having a first end coupled with the shielding unit and a second end coupled to ground.

The present electronic device capable of releasing ESD further includes a first point discharge unit having a first end coupled to the shielding unit and a second end being a point, and a second point discharge unit having a first end being a point and a second end coupled to ground.

In the present electronic device capable of releasing ESD, the shielding unit may include a piece of metal net, a piece of metal foil, or metallic compound plated on the housing.

In the present electronic device capable of releasing ESD, the component to be protected could be a circuit, a chip, an integrated circuit or a frame of a liquid crystal display panel.

In the present electronic device capable of releasing ESD, the seam may be an outlet for heat sinking.

The present electronic device capable of releasing ESD may be a mobile phone, a notebook or a personal digital assistant.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a conventional notebook.

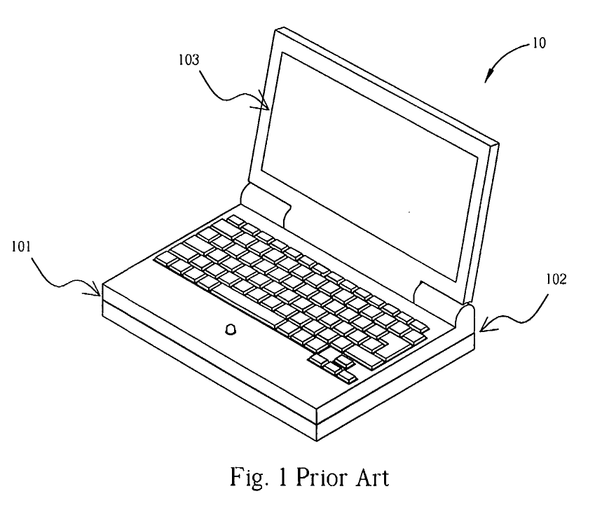

FIG. 2 is a sectional diagram of an electronic device of the prior art.

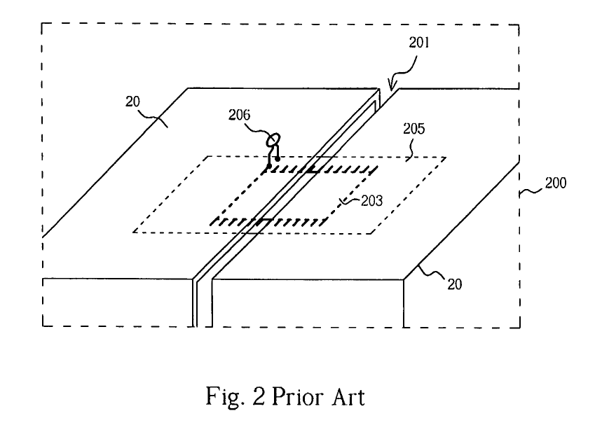

FIG. 3 is a sectional diagram of a first embodiment of the present electronic device capable of releasing ESD.

FIG. 4 is a sectional diagram of a second embodiment of the present electronic device capable of releasing ESD.

FIG. 5 is a sectional diagram of a third embodiment of the present electronic device capable of releasing ESD.

### DETAILED DESCRIPTION

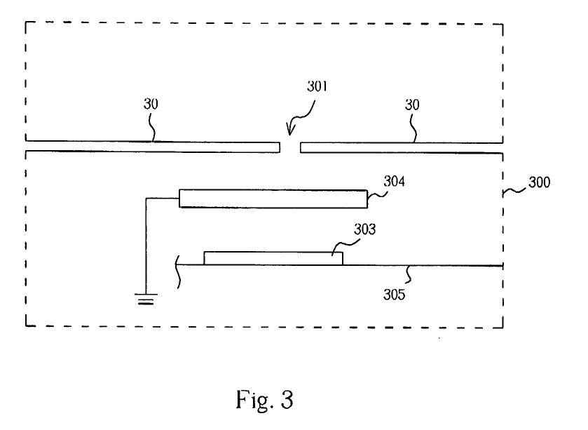

Please refer to FIG. 3. FIG. 3 is a sectional diagram of a first embodiment of the present electronic device capable of releasing ESD. The present electronic device 300 includes a housing 30 with a seam 301, a circuit board 305, and a component installed on the circuit board 305, e.g. an IC 303. In the present invention, a shielding unit 304 is installed between the seam 301 and the IC 303, and is coupled to ground. The shielding unit 304, being a conductor, may include a piece of metal net, a piece of metal foil, metallic compound plated or sputtered on the housing 30, or other conductive matter. The shielding unit 304 is utilized to conduct the charges that enter the electronic device 300 from outside the housing 30 through the seam 301 to ground such that the IC 303 can be saved from being destroyed by the ESD.

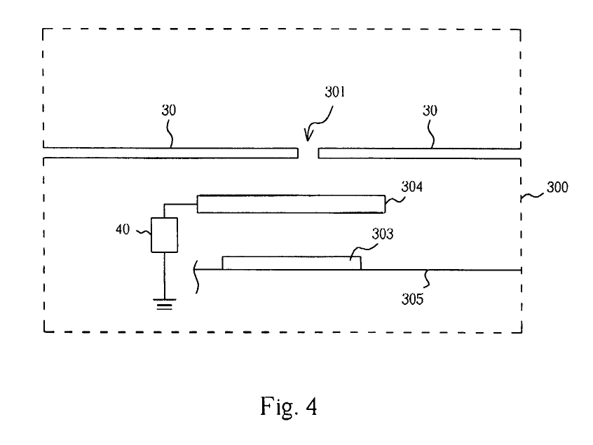

Please refer to FIG. 4. FIG. 4 is a sectional diagram of a second embodiment of the present electronic device capable of releasing ESD. In the second embodiment illustrated in FIG. 4, a filter 40 is coupled to the shielding unit 304 and ground. Since the electrostatic discharge is a burst and the discharge voltage may exceed tens of kilovolts, the filter 40 is adopted in the second embodiment in order to prevent the burst of ESD from releasing to ground directly and hence destroying the surrounding components. Beside of the filter 40, a transient voltage suppressor (TVS) or a varistor may also be utilized to achieve the goal in other embodiments.

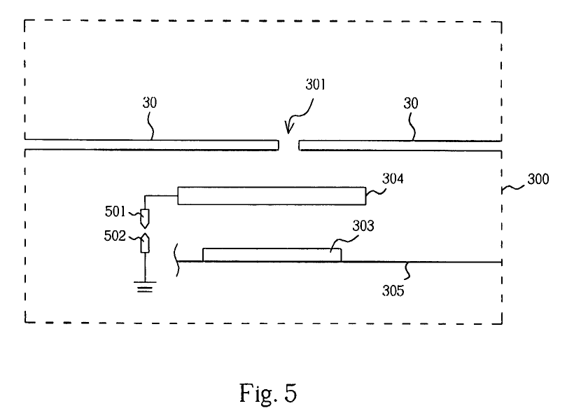

Please refer to FIG. 5. FIG. 5 is a sectional diagram of a third embodiment of the present electronic device capable of releasing ESD. In the third embodiment, the electronic device 300 of the present invention further adopts a set of point discharge device including a first point discharge unit 501 and a second point discharge unit 502. One end of the first point discharge unit 501 is coupled to the shielding unit 304, and the other end of the first point discharge unit 501 is a point part called the first point part. One end of the second point discharge unit 502 is coupled to ground, and the other end of the second point discharge unit 502 is also a point part called the second point part. The first point part and the second point part are opposite to each other but not connected to each other, utilized to conduct charges on the shielding unit 304 to ground. Similarly, the point discharge units 501 and 502 help the charges of the electrostatic waves not to release to ground directly. Hence the surrounding components are kept away from the burst of the ESD.

In summary, the present invention provides an electronic device capable of releasing ESD. A simple shielding unit and related components are installed between the seam of the housing and circuits. Hence the discharge path is changed and the charges would be conducted to ground instead of hitting ICs or circuits. The present invention may further adopt filters coupled to the shielding unit such that the electrostatic charges may be conducted to ground indirectly. Point discharge devices may also help the present invention to prevent the burst of ESD from destroying circuits of other components of the electronic device. To prevent circuits, ICs and other components from being destroyed by ESD, the shielding unit introduced by the present invention may be installed between a display panel and a seam of the housing, next to a heat outlet, or near other seams of the housing. The present invention can be applied to mobile phones, notebooks, personal digital assistants (PDAs), or any other electronic devices.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic device capable of releasing electrostatic discharge (ESD), the electronic device comprising:
a housing with a seam;
a component installed inside the housing; and
a shielding unit installed between the seam and the component, the shielding unit being utilized to conduct charges emitted into the housing through the seam.

2. The electronic device capable of releasing electrostatic discharge of claim 1 wherein the shielding unit is coupled to ground.

3. The electronic device capable of releasing electrostatic discharge of claim 1 further comprising a filter, the filter comprising:
a first end, coupled to the shielding unit; and
a second end, coupled to ground.

4. The electronic device capable of releasing electrostatic discharge of claim 1 further comprising a transient voltage suppressor (TVS), the TVS comprising:
a first end, coupled to the shielding unit; and
a second end, coupled to ground.

5. The electronic device capable of releasing electrostatic discharge of claim 1 further comprising a varistor, the varistor comprising:
a first end, coupled to the shielding unit; and
a second end, coupled to ground.

6. The electronic device capable of releasing electrostatic discharge of claim 1 further comprising:
a first point discharge unit comprising:
a first end, coupled to the shielding unit; and
a second end, being a first point part; and
a second point discharge unit comprising:
a first end, being a second point part; and
a second end, coupled to ground;
wherein the first point part and the second point part are utilized to conduct charges on the shielding unit to ground.

7. The electronic device capable of releasing electrostatic discharge of claim 1 wherein the shielding unit comprises a piece of metal net.

8. The electronic device capable of releasing electrostatic discharge of claim 1 wherein the shielding unit comprises a piece of metal foil.

9. The electronic device capable of releasing electrostatic discharge of claim 1 wherein the shielding unit comprises metallic compound plated on the housing.

10. The electronic device capable of releasing electrostatic discharge of claim 1 wherein the component is a circuit.

11. The electronic device capable of releasing electrostatic discharge of claim 1 wherein the component is a chip.

12. The electronic device capable of releasing electrostatic discharge of claim 1 wherein the component is an integrated circuit.

13. The electronic device capable of releasing electrostatic discharge of claim 1 wherein the component is a frame of a liquid crystal display panel.

14. The electronic device capable of releasing electrostatic discharge of claim 1 wherein the seam is an outlet for heat sinking.

15. The electronic device capable of releasing electrostatic discharge of claim 1 being a mobile phone.

16. The electronic device capable of releasing electrostatic discharge of claim 1 being a notebook.

17. The electronic device capable of releasing electrostatic discharge of claim 1 being a personal digital assistant (PDA).
